(19) United States
(12) Patent Application Publication
(10) Pub. No.: US 2024/0274544 A1
(43) Pub. Date: Aug. 15, 2024

(54) SEMICONDUCTOR MODULE AND SEMICONDUCTOR DEVICE

(71) Applicant: Mitsubishi Electric Corporation, Tokyo (JP)

(72) Inventors: Makoto HASHIKAWA, Fukuoka (JP); Takuya SHIRAISHI, Fukuoka (JP); Yasuo FUJITA, Fukuoka (JP); Hayato NAGAMIZU, Fukuoka (JP); Koji TAMAKI, Tokyo (JP)

(73) Assignee: Mitsubishi Electric Corporation, Tokyo (JP)

(21) Appl. No.: 18/474,374

(22) Filed: Sep. 26, 2023

(30) Foreign Application Priority Data
Feb. 14, 2023 (JP) 2023-021111

(51) Int. Cl. H01L 23/544; H01L 23/498; H01L 25/065

(52) U.S. Cl. CPC H01L 23/544; H01L 23/49811; H01L 23/49838; H01L 25/0655; H01L 24/48; H01L 2223/5444; H01L 2224/48137; H01L 2224/48175; H01L 2224/48245; H01L 2924/182

(57) ABSTRACT

A semiconductor module according to the present disclosure includes a package, a main terminal protruding from the package, a control terminal protruding from the package, and at least one identification terminal protruding from the package, in which information on a product is identifiable from an electrical characteristic, an appearance, or a shape of the at least one identification terminal.

### BACKGROUND

### Field

The present disclosure relates to a semiconductor module and a semiconductor device.

### Background

JP 2021-007119 A discloses a semiconductor device including a semiconductor module, a mounting board, and a heat radiation fin, and capable of identifying a product. The semiconductor module includes a module main body having first and second main surfaces that are opposite to each other, and a terminal protruding from a side surface of the module main body and bent toward the first main surface side. The mounting board is placed on the first main surface side and is connected to the terminal. The heat radiation fin is placed on the second main surface side. A screw fits a fitting portion of the module main body to the heat radiation fin from the first main surface side. The mounting board is provided with an opening at a portion facing the fitting portion. The type of the product is printed on the first main surface and is exposed from the opening of the mounting board.

In JP 2021-007119 A, the product is identified by checking the print through the opening of the mounting board. At this time, it may be difficult to check the print depending on the structure of the mounting board.

### SUMMARY

The present disclosure has been made to solve the foregoing problem, and it is an object of the present disclosure to provide a semiconductor module and a semiconductor device with which information on a product can be easily checked.

The features and advantages of the present disclosure may be summarized as follows.

According to an aspect of the present disclosure, a semiconductor module includes a package, a main terminal protruding from the package, a control terminal protruding from the package and at least one identification terminal protruding from the package, wherein information on a product is identifiable from an electrical characteristic, an appearance, or a shape of the at least one identification terminal.

Other and further objects, features and advantages of the disclosure will appear more fully from the following description.

### BRIEF DESCRIPTION OF DRAWINGS

FIG. 1 is a plan view of a semiconductor module according to a first embodiment.

FIG. 2 is an enlarged view of the semiconductor module according to the first embodiment.

FIG. 3 is a cross-sectional view of a semiconductor device according to the first embodiment.

FIG. 4 is a view illustrating a short lead according to the first embodiment.

FIGS. 5A to 5E are views illustrating the connection states of the identification terminals according to the first embodiment.

FIG. 6A is a front view of the semiconductor device according to the first embodiment.

FIG. 6B is a side view of the semiconductor device according to the first embodiment.

FIG. 6C is a plan view of the semiconductor device according to the first embodiment.

FIGS. 7A to 7D are views illustrating the connection states of the identification terminals according to a second embodiment.

FIGS. 8A to 8D are views illustrating the connection states of the identification terminals according to a third embodiment.

FIG. 9 is a plan view of a semiconductor device according to a modified example of the third embodiment.

FIG. 10 is an enlarged view of a semiconductor module according to a fourth embodiment.

### DESCRIPTION OF EMBODIMENTS

A semiconductor module and a semiconductor device according to each embodiment will be described with reference to the accompanying drawings. Components identical or corresponding to each other are indicated by the same reference characters, and repeated description of them is avoided in some cases.

### First Embodiment

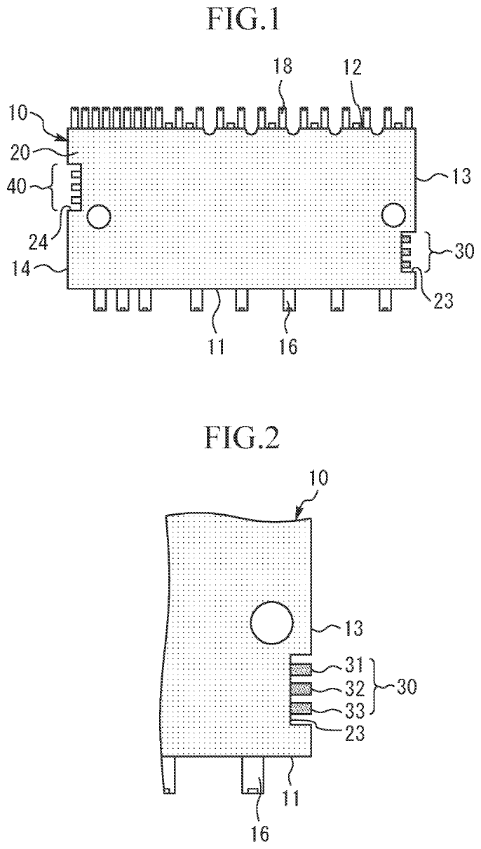

FIG. 1 is a plan view of a semiconductor module 10 according to a first embodiment. The semiconductor module 10 includes a package 20, and main terminals 16 and control terminals 18 each protruding from the package 20. The package 20 is formed of an insulating sealing resin, for example. The main terminals 16 are terminals through which a main current of a semiconductor chip 22 described below, which is housed in the package 20, flows. The control terminals 18 are terminals for controlling on/off of the semiconductor chip 22. The main terminals 16 and the control terminals 18 respectively protrude from a pair of opposite side surfaces 11 and 12 of the package 20.

The semiconductor module 10 includes a plurality of identification terminals 30 protruding from the package 20. FIG. 2 is an enlarged view of the semiconductor module 10 according to the first embodiment. The semiconductor module 10 includes three identification terminals 31, 32, and 33 as the identification terminals 30, for example. The identification terminals 31, 32, and 33 protrude from a side surface of the package 20 different from the side surface 11 from which the main terminals 16 protrude and the side surface 12 from which the control terminals 18 protrude. Specifically, the identification terminals 31, 32, and 33 protrude from one of a pair of side surfaces 13 and 14 (i.e., the side surface 13) of the package 20 connecting the side surfaces 11 and 12. The side surface 13 has a recess portion 23 formed therein. The identification terminals 31, 32, and 33 are provided in the recess portion 23.

According to the semiconductor module 10 of the present embodiment, information on a product of the semiconductor module 10 can be identified from the electrical characteristics of the identification terminals 31, 32, and 33 as described below. Examples of the information on the product include a rated value of the product.

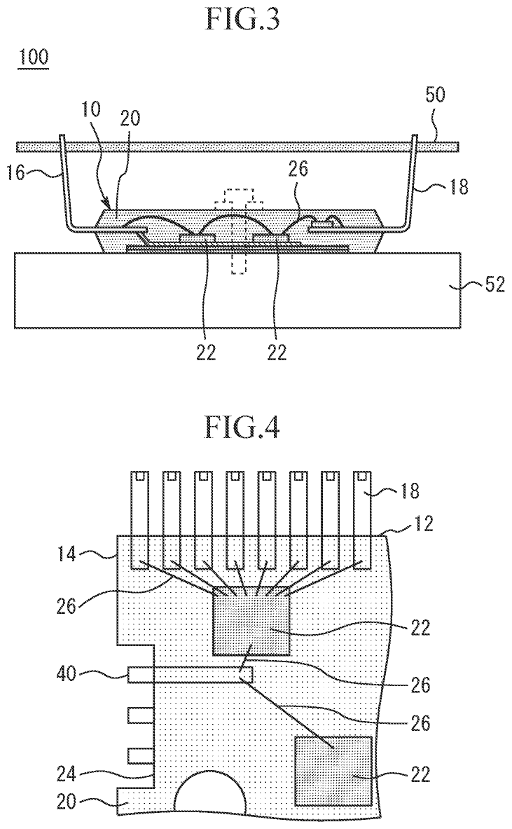

FIG. 3 is a cross-sectional view of a semiconductor device 100 according to the first embodiment. The semiconductor device 100 includes the semiconductor module 10, and a substrate 50 provided to cover the package 20 and connected to the main terminals 16 or the control terminals 18. The semiconductor device 100 may also include a heat radiation fin 52 below the semiconductor module 10. The package 20 houses the semiconductor chip 22. The semiconductor chip 22 is electrically connected to the main terminals 16 and the control terminals 18 via wires 26, for example.

The substrate 50 is a control substrate for controlling the semiconductor module 10, for example. The substrate 50 is connected to the main terminals 16 and the control terminals 18 with solder, for example. The main terminals 16 and the control terminals 18 are bent upward so as to be connected to the substrate 50. Note that FIG. 1 only illustrates the base portions of the main terminals 16 and the control terminals 18.

FIG. 4 is a view illustrating a short lead 40 according to the first embodiment. The semiconductor module 10 includes the short lead 40 protruding from the package 20. The short lead 40 protrudes from the side surface 14 of the package 20, for example. The side surface 14 has a recess portion 24 formed therein. The short lead 40 is provided in the recess portion 24. The short lead 40 is electrically connected to the control terminals 18 via the semiconductor chip 22 in the package 20. The short lead 40 is a dummy terminal that is a redundant terminal not arranged on the side surface 12 and is not planned to be used. Such a configuration in which terminals protrude from four side surfaces of a sealing resin is rare in the field of power semiconductors. Note that none of the identification terminals 31, 32, and 33 is connected to the control terminals 18 in the package 20.

Next, a method of identifying information on the product using the identification terminals 30 will be described. In the present embodiment, information on the product is identified from a resistance value between the plurality of identification terminals 30, for example. The number of the identification terminals 30 may be two or more, and is preferably three or more. Herein, an example in which three identification terminals 31, 32, and 33 are provided is described.

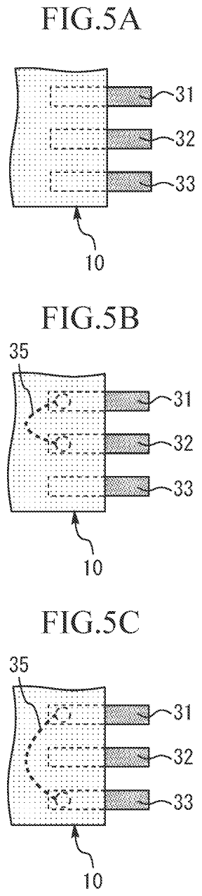

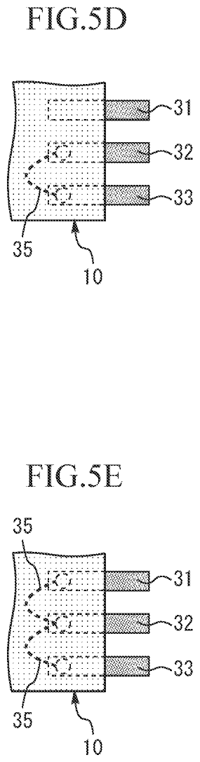

FIGS. 5A to 5E are views illustrating the connection states of the identification terminals 31, 32, and 33 according to the first embodiment. In the state of FIG. 5A, the identification terminals 31, 32, and 33 are not connected to each other. In the state of FIG. 5B, the identification terminals 31 and 32 are electrically connected via a conductor 35, such as a wire. In the state of FIG. 5C, the identification terminals 31 and 33 are electrically connected via the conductor 35. In the state of FIG. 5D, the identification terminals 32 and 33 are electrically connected via the conductor 35. In the state of FIG. 5E, the identification terminals 31, 32, and 33 are electrically connected to each other via the conductors 35.

In the present embodiment, a rated value is identified based on a combination of a pair of identification terminals 30 that are electrically connected. That is, rated values are assigned to the five states in FIGS. 5A to 5E. An operator is able to identify a rated value by measuring a resistance value between the identification terminals 31 and 32, a resistance value between the identification terminals 32 and 33, and a resistance value between the identification terminals 31 and 33. In this manner, in the present embodiment, information on the product can be identified by measuring resistance values between, among the three or more identification terminals 30, two or more different pairs of identification terminals 30. At this time, at least two identification terminals 30 of the three or more identification terminals 30 may be electrically connected in the package 20, or none of the identification terminals 30 may be connected.

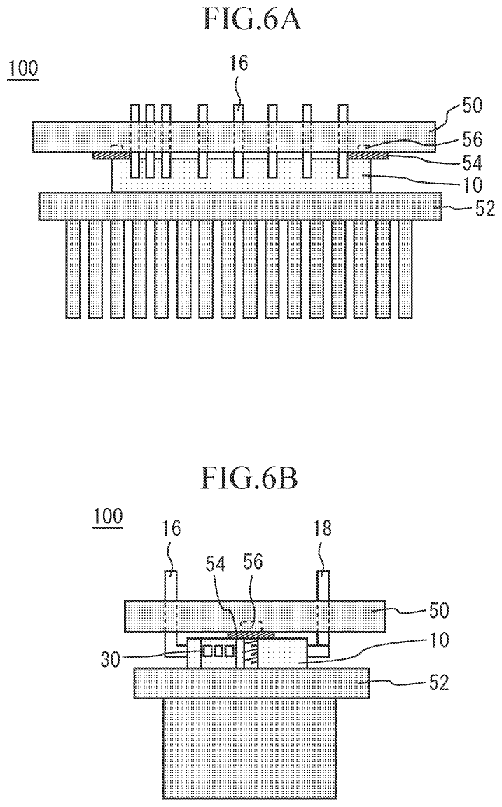

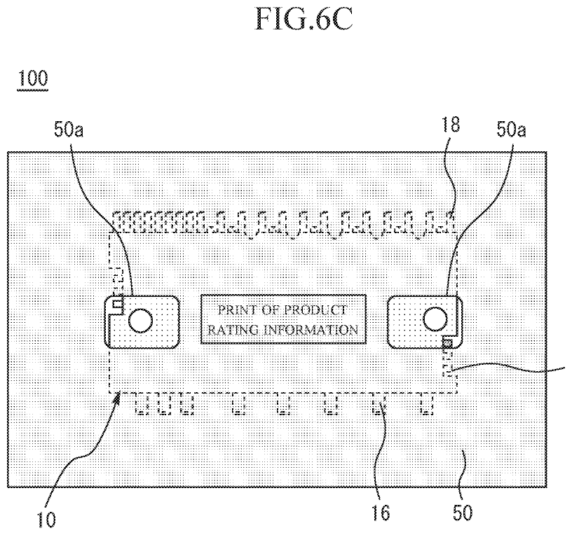

FIG. 6A is a front view of the semiconductor device 100 according to the first embodiment. FIG. 6B is a side view of the semiconductor device 100 according to the first embodiment. FIG. 6C is a plan view of the semiconductor device 100 according to the first embodiment. The semiconductor module 10 is attached to the heat radiation fin 52 with screws 56 from the upper surface side of the semiconductor module 10. A washer 54 is provided between each screw 56 and the upper surface of the package 20. The substrate 50 has an opening 50a formed therein at a portion facing each screw 56. The upper surface of the package 20 is provided with a print of product rating information. Checking the print of the product rating information can identify a rated value. However, there may be a case where the print is difficult to check depending on the size of the opening 50a of the substrate 50, for example.

In contrast, in the present embodiment, information on the product can be identified from the electrical characteristics of the plurality of identification terminals 30. Therefore, information on the product can be easily checked without the need to check the print from above the substrate 50 via the opening 50a. The operator is able to check the information on the product by measuring the electrical characteristics of the identification terminals 30 from the side of the semiconductor module 10 in a state where the heat radiation fin 52 and the substrate 50 are attached to the semiconductor module 10, for example. Therefore, there is no need to detach the semiconductor module 10 from the heat radiation fin 52 or the substrate 50 to check the information on the product. In addition, there is no need to increase the size of the opening 50a of the substrate 50 for viewing of the print.

The identification terminals 30 are not attached to the substrate 50. Therefore, the identification terminals 30 need not to be bent like the main terminals 16 and the control terminals 18. Further, the identification terminals 30 may be short because they are not connected to the substrate 50. This can suppress short-circuit between the identification terminals 30 and a peripheral device. As illustrated in FIG. 2, the length of a portion of each of the identification terminals 30 protruding from the package 20 is preferably less than or equal to the amount of recess of the recess portion 23. This can improve the insulating property and further suppress short-circuit.

The present embodiment has illustrated an example in which a rated value is identified using the identification terminals 30. Information on the product that can be identified using the identification terminals 30 is not limited to a rated value, and may be any information on the product, such as the presence or absence of a short-circuit protection function, the presence or absence of a bootstrap diode mounted, the presence or absence of a circuit for protection against a drop in control power-supply voltage, the presence or absence of an overheat protection function, and the presence or absence of a braking circuit.

In the present embodiment, information on the product is identified from a resistance value between the plurality of identification terminals. However, the present disclosure is not limited thereto. For example, information on the product may be identified from electrical characteristics other than the resistance value.

The structures of the semiconductor module 10 and the semiconductor device 100 described in the present embodiment are only exemplary, and the present disclosure is not limited thereto. For example, each terminal of the semiconductor module 10 may be provided on any surface of the package 20. For example, the main terminals 16 and the control terminals 18 may protrude from one side surface.

The package 20 may include the semiconductor chip 22 made with a wide bandgap semiconductor. Examples of the wide bandgap semiconductor include silicon carbide, a gallium nitride-based material, and diamond.

In the present embodiment, information on the product is identified from electrical characteristics between the plurality of identification terminals 30. However, the present disclosure is not limited thereto. For example, as described in the following embodiment, information on the product may be identified from the electrical characteristics, appearance, or shape of one or more identification terminals 30.

These modifications can be appropriately applied to semiconductor modules and semiconductor devices according to embodiments below. Meanwhile, for the semiconductor modules and the semiconductor devices according to the embodiments below, dissimilarities with the first embodiment will mainly be explained as they have many similarities with the first embodiment.

### Second Embodiment

The present embodiment differs from the first embodiment in the method of identifying information on a product using the identification terminals 30. In the present embodiment, information on the product is identified based on whether or not each of the plurality of identification terminals 30 is electrically connected to the main terminal 16. A semiconductor module 210 of the present embodiment includes three identification terminals 31, 32, and 33 as the plurality of identification terminals 30, for example.

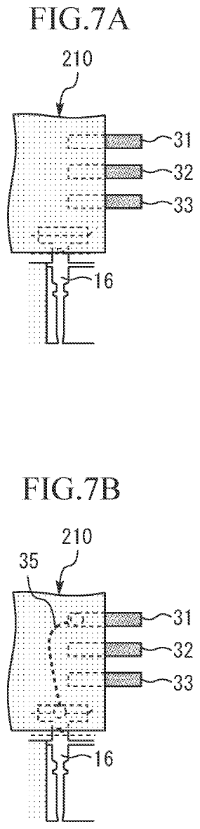

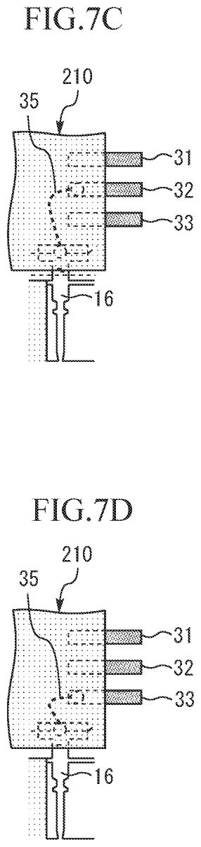

FIGS. 7A to 7D are views illustrating the connection states of the identification terminals 31, 32, and 33 according to a second embodiment. In the state of FIG. 7A, none of the identification terminals 31, 32, and 33 is electrically connected to the main terminal 16. In the state of FIG. 7B, the identification terminal 31 and the main terminal 16 are electrically connected via the conductor 35, such as a wire, in the package 20. In the state of FIG. 7C, the identification terminal 32 and the main terminal 16 are electrically connected via the conductor 35 in the package 20. In the state of FIG. 7D, the identification terminal 33 and the main terminal 16 are electrically connected via the conductor 35 in the package 20. In this manner, at least one of the plurality of identification terminals 31, 32, and 33 may be electrically connected to the main terminal 16 in the package 20, or none of the identification terminals 31, 32, and 33 may be connected thereto.

An operator is able to identify a rated value by measuring a resistance value between each of the identification terminals 31, 32, and 33 and the main terminal 16, for example. Although FIGS. 7A to 7D illustrate four connection states, it is possible to identify eight rated values, for example, by assign the rated values to whether or not the identification terminals 31, 32, and 33 are electrically connected to the main terminal 16. Examples of the eight rated values include 5A, 10A, 15A, 20A, 25A, 30A, 50A, and 75A. In addition, the number of pieces of information on the product that can be identified may be increased or reduced in accordance with the number of the identification terminals 30. For example, only one identification terminal 30 may be provided so that two types of information may be identified based on whether or not the identification terminal 30 is electrically connected to the main terminal 16.

### Third Embodiment

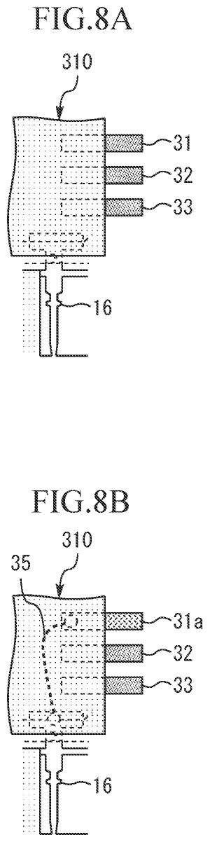

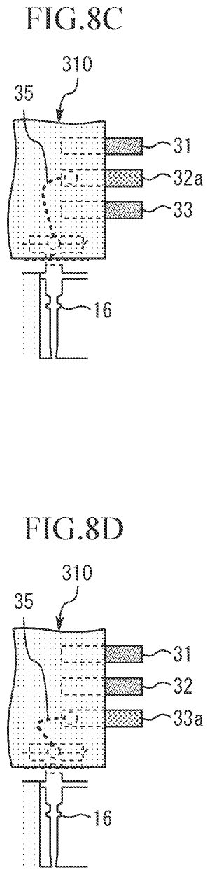

FIGS. 8A to 8D are views illustrating the connection states of the identification terminals 30 according to a third embodiment. A semiconductor module 310 of the present embodiment differs from the semiconductor module 210 of the second embodiment in that one or more of the plurality of identification terminals 30 that is/arc electrically connected to the main terminal 16 and thus is/are at the same potential as the main terminal 16 is/are plated. The other configurations are similar to the configurations in the second embodiment.

Each of the identification terminals 31, 32, and 33 illustrated in FIGS. 8A to 8D is not electrically connected to the main terminal 16, and is not plated. Each of identification terminals 31a, 32a, and 33a illustrated in FIGS. 8B, 8C, and 8D is electrically connected to the main terminal 16, and is plated. In this manner, the plurality of identification terminals 30 may include plated identification terminals 30 and non-plated identification terminals 30, and all of the identification terminals 30 may be plated, or none of the identification terminals 30 may be plated.

In the present embodiment, it is also possible to identify information on the product by visually checking the presence or absence of plating. At this time, it is possible to visually check the presence or absence of plating from the side of the semiconductor module 310 without detaching the heat radiation fin 52 or the substrate 50.

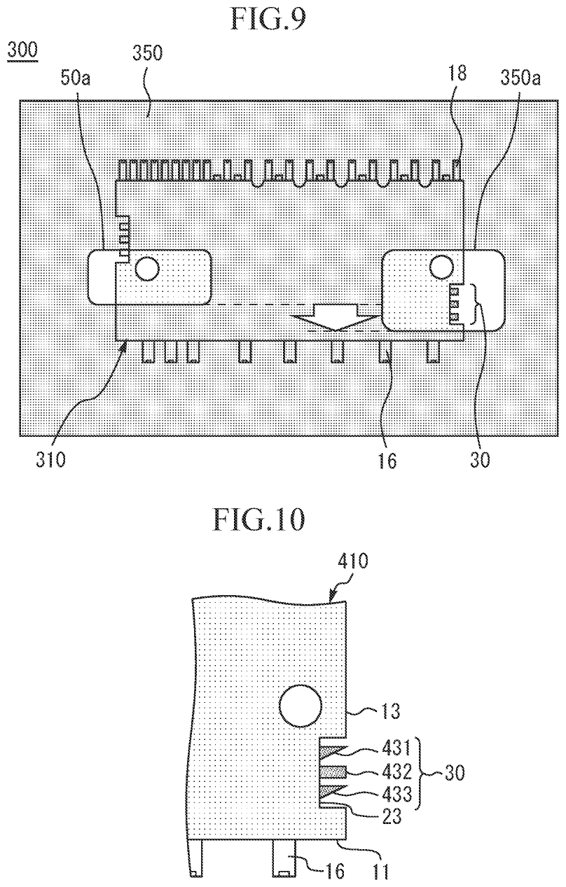

FIG. 9 is a plan view of a semiconductor device 300 according to a modified example of the third embodiment. A substrate 350 is provided above the semiconductor module 310. An opening 350a of the substrate 350 may be enlarged to a position immediately above the identification terminals 30 as an opening for checking the identification terminals. This can further increase visibility. This can also increase the insulating property between the identification terminals 30 and the substrate 350.

Note that in the present embodiment, electrical connection between each of the identification terminals 30 and the main terminal 16 is combined with plating. However, the present disclosure is not limited thereto. For example, information on the product may be identified based only on whether or not each identification terminal 30 is plated. That is, information on the product may be identified based only on the appearance of the plurality of identification terminals 30. Alternatively, the present embodiment may be combined with the first embodiment.

### Fourth Embodiment

FIG. 10 is an enlarged view of a semiconductor module 410 according to a fourth embodiment. The present embodiment differs from the first embodiment in that information on a product is identified from the shapes of the plurality of identification terminals 30. The semiconductor module 410 includes three identification terminals 431, 432, and 433 as the plurality of identification terminals 30, for example. The shape of each of the identification terminals 431, 432, and 433 is selected from two shapes according to rated values. For example, the shape of each of the identification terminals 431, 432, and 433 is selected from a triangle and a quadrangle. In the example of FIG. 10, the identification terminals 431 and 433 are triangular as seen in plan view, and the identification terminal 432 is quadrangular as seen in plan view.

In the present embodiment, information on the product, such as a rated value, may be identified based on a combination of the shapes of the identification terminals 431, 432, and 433, The plurality of identification terminals 431, 432, and 433 may include identification terminals with different shapes, or all of the identification terminals may have the same shape.

In the present embodiment, information on the product may be identified from the appearance of the plurality of identification terminals 30. However, the present disclosure is not limited thereto. For example, the present embodiment may be combined with the first embodiment or the second embodiment so that information on the product may be identified from the electrical characteristic and the appearance of the plurality of identification terminals 30.

The shape of each of the plurality of identification terminals 431, 432, and 433 may be selected from three or more shapes. Accordingly, more types of information on the product may be identified from the plurality of identification terminals 431, 432, and 433. It is acceptable as long as the number of the plurality of identification terminals 30 is one or more. Even when there is only one identification terminal 30 provided, information on the product may be identified from the shape of the identification terminal 30.

Meanwhile, technical features explained in each embodiment may be appropriately combined to use.

Hereinafter, various aspects of the present disclosure will be collectively described as appendixes.

### APPENDIX 1

A semiconductor module comprising:
a package;
a main terminal protruding from the package;
a control terminal protruding from the package; and
at least one identification terminal protruding from the package;
wherein information on a product is identifiable from an electrical characteristic, an appearance, or a shape of the at least one identification terminal.

### APPENDIX 2

The semiconductor module according to appendix 1, wherein the information on the product is a rated value of the product.

### APPENDIX 3

The semiconductor module according to appendix 1 or 2, wherein the at least one identification terminal includes a plurality of identification terminals.

### APPENDIX 4

The semiconductor module according to appendix 3, wherein the information on the product is identifiable from a resistance value between the plurality of identification terminals.

### APPENDIX 5

The semiconductor module according to appendix 3.
wherein the at least one identification terminal includes three or more identification terminals, and
the information on the product is identifiable by measuring resistance values between, among the three or more identification terminals, two or more different pairs of identification terminals.

### APPENDIX 6

The semiconductor module according to appendix 5, wherein at least two identification terminals of the three or more identification terminals are electrically connected in the package.

### APPENDIX 7

The semiconductor module according to appendix 3, wherein at least one of the plurality of identification terminals is electrically connected to the main terminal in the package.

### APPENDIX 8

The semiconductor module according to appendix 3, wherein the plurality of identification terminals include a plated identification terminal and a non-plated identification terminal.

### APPENDIX 9

The semiconductor module according to appendix 3, wherein the plurality of identification terminals include identification terminals with different shapes.

### APPENDIX 10

The semiconductor module according to any one of appendixes 1 to 9, wherein the at least one identification terminal protrudes from a side surface of the package different from a side surface from which the main terminal protrudes and a side surface from which the control terminal protrudes.

### APPENDIX 11

The semiconductor module according to any one of appendixes 1 to 10, further comprising a short lead protruding from the package and connected to the control terminal in the package.

### APPENDIX 12

The semiconductor module according to any one of appendixes 1 to 11.
wherein a recess portion is formed in a side surface of the package, and
the at least one identification terminal is provided in the recess portion.

### APPENDIX 13

The semiconductor module according to any one of appendixes 1 to 12, wherein the package includes a semiconductor chip made with a wide bandgap semiconductor.

### APPENDIX 14

The semiconductor module according to appendix 13, wherein the wide bandgap semiconductor is silicon carbide, a gallium nitride-based material, or diamond.

### APPENDIX 15

A semiconductor device comprising:
the semiconductor module according to any one of appendixes 1 to 14; and
a substrate provided to cover the package and connected to the main terminal or the control terminal.

With the semiconductor module according to the present disclosure, information on the product can be identified from the electrical characteristics, appearance, or shape of the at least one identification terminal. Therefore, the information on the product can be easily checked without the need to check a print.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2023-021111, filed on Feb. 14, 2023 including specification, claims, drawings and summary, on which the Convention priority of the present application is based, are incorporated herein by reference in its entirety.

1. A semiconductor module comprising:
a package;
a main terminal protruding from the package;
a control terminal protruding from the package; and
at least one identification terminal protruding from the package,
wherein information on a product is identifiable from an electrical characteristic, an appearance, or a shape of the at least one identification terminal.

2. The semiconductor module according to claim 1, wherein the information on the product is a rated value of the product.

3. The semiconductor module according to claim 1, wherein the at least one identification terminal includes a plurality of identification terminals.

4. The semiconductor module according to claim 3, wherein the information on the product is identifiable from a resistance value between the plurality of identification terminals.

5. The semiconductor module according to claim 3,
wherein the at least one identification terminal includes three or more identification terminals, and
the information on the product is identifiable by measuring resistance values between, among the three or more identification terminals, two or more different pairs of identification terminals.

6. The semiconductor module according to claim 5, wherein at least two identification terminals of the three or more identification terminals are electrically connected in the package.

7. The semiconductor module according to claim 3, wherein at least one of the plurality of identification terminals is electrically connected to the main terminal in the package.

8. The semiconductor module according to claim 3, wherein the plurality of identification terminals include a plated identification terminal and a non-plated identification terminal.

9. The semiconductor module according to claim 3, wherein the plurality of identification terminals include identification terminals with different shapes.

10. The semiconductor module according to claim 1, wherein the at least one identification terminal protrudes from a side surface of the package different from a side surface from which the main terminal protrudes and a side surface from which the control terminal protrudes.

11. The semiconductor module according to claim 1, further comprising a short lead protruding from the package and connected to the control terminal in the package.

12. The semiconductor module according to claim 1,
wherein a recess portion is formed in a side surface of the package, and
the at least one identification terminal is provided in the recess portion.

13. The semiconductor module according to claim 1, wherein the package includes a semiconductor chip made with a wide bandgap semiconductor.

14. The semiconductor module according to claim 13, wherein the wide bandgap semiconductor is silicon carbide, a gallium nitride-based material, or diamond.

15. A semiconductor device comprising:
the semiconductor module according to claim 1; and
a substrate provided to cover the package and connected to the main terminal or the control terminal.
